(19) United States
(12) Patent Application Publication
(10) Pub. No.: US 2025/0273490 A1
(43) Pub. Date: Aug. 28, 2025

(54) DIE EJECTOR

(71) Applicant: FLC, Cheonan-si (KR)

(72) Inventors: Ganghyun MUN, Cheonan-si (KR); Sunghee CHO, Asan-si (KR)

(21) Appl. No.: 19/015,625

(22) Filed: Jan. 9, 2025

(30) Foreign Application Priority Data
Jan. 10, 2024 (KR) 10-2024-0004096

(51) Int. Cl. H01L 21/67

(52) U.S. Cl. CPC H01L 21/67132

(57) ABSTRACT

The present disclosure relates to a die ejector, which separates a pickup-target chip from dicing tape, and more specifically, to a die ejector including a plurality of vertical driving units in a subordinate structure. The die ejector may include an ejector module including an ejecting block that comes into contact with dicing tape, a first driving block configured to perform, through upward or downward movement thereof, first upward or downward movement of the ejecting block, a second driving block configured to perform, through upward or downward movement thereof, second upward or downward movement of the ejecting block, a first vertical driving unit configured to move the first and second driving blocks upward or downward simultaneously, and a second vertical driving unit configured to move only the second driving block upward or downward.

### CROSS-REFERENCE TO RELATED APPLICATION

This application claims priority to Korean Patent Application No. 10-2024-0004096, filed on Jan. 10, 2024, which is incorporated herein by reference in its entirety.

### BACKGROUND

### Technical Field

The present disclosure relates to a die ejector, which separates a pickup-target chip from dicing tape, and more specifically, to a die ejector including a plurality of vertical driving units in a subordinate structure.

### Related Art

In a packaging process, which is a semiconductor back-end process, bonding refers to attaching a wafer chip to a substrate. One type of bonding, die bonding, involves attaching a semiconductor chip onto a lead frame or a printed circuit board (PCB) to establish an electrical connection of the semiconductor chip.

As shown in FIG. 1, in such die bonding, each semiconductor chip C that has undergone a dicing process exists in a state where the semiconductor chip C remains individually positioned and attached to dicing tape T. Typically, the semiconductor chip C is picked up using a plunger P and then placed onto a package substrate. Here, the semiconductor chip C, which is horizontally adhered to dicing tape T, is not easily separated due to adhesive. If excessive suction is applied, physical damage may occur to the semiconductor chip C. Therefore, a solution is needed to facilitate separation of the dicing tape T and the semiconductor chip C.

A structure that enables the separation of the semiconductor chip C is an ejector E. Generally, the ejector E applies pressure to a lower surface of the dicing tape T from beneath with an area smaller than that of the semiconductor chip C while simultaneously holding the dicing tape T by suction, thereby facilitating the separation of the dicing tape T from the semiconductor chip C, and assisting the pickup operation of the plunger P.

A conventional art related to such an ejector (hereinafter referred to as “conventional art”) is disclosed in Korean Patent No. 10-1931127. The conventional technology discloses a semiconductor manufacturing apparatus that includes a lift-up unit that pushes up a die from beneath dicing tape, and a collet that holds the die by suction. The lift-up unit includes a first unit having a plurality of rectangular blocks that contact the dicing tape, and a second unit having a plurality of concentric circular blocks each of which independently transmits up-and-down movement to a corresponding rectangular block. The semiconductor manufacturing apparatus allows the lift-up unit to be easily modified according to the type of products.

However, the conventional technology requires a plurality of vertical driving units corresponding to the number of lift-up blocks (ejecting blocks), leading to excessive costs. Additionally, controlling the multiple lift-up blocks necessitates multi-axis motion position control technology. Therefore, there is a need for technology related to an ejector that has a simple operating structure and enables low-cost implementation.

### SUMMARY

The present disclosure has been devised to solve the above problem, and an object of the present disclosure is to provide a die ejector, which may not only reduce costs compared to providing a vertical driving unit for each ejecting block, but may also simplify a control algorithm of vertical driving units, and in which when a first vertical driving unit operates, first and second driving blocks move upward or downward simultaneously, ensuring that an upper level of each ejecting block remains consistent during movement to a die separation position or a standby position.

A die ejector according to an embodiment of the present disclosure may include: an ejector module including an ejecting block that comes into contact with dicing tape; a first driving block configured to perform, through upward or downward movement thereof, first upward or downward movement of the ejecting block; a second driving block configured to perform, through upward or downward movement thereof, second upward or downward movement of the ejecting block; a first vertical driving unit configured to move the first and second driving blocks upward or downward simultaneously; and a second vertical driving unit configured to move only the second driving block upward or downward.

The first vertical driving unit may include a first lifting shaft, and a first lifting element coupled to the first driving block and configured to move upward or downward under constraint by the first lifting shaft.

The second vertical driving unit may include a second lifting shaft, and a second lifting element coupled to the second driving block and configured to move upward or downward under constraint by the second lifting shaft.

The first driving block may include a hollow space therein. The second driving block may be installed in the hollow space.

The second lifting shaft and the second lifting element of the second vertical driving unit may be installed in the hollow space of the first driving block.

The first driving block may include a guide portion provided on an inner surface thereof. The second driving block may include a sliding portion constrained by the guide portion so that the second driving block moves upward or downward along the guide portion.

The die ejector may include a stopper configured to limit upward movement of the first driving block so that when the second vertical driving unit operates, only the second driving block moves upward.

The stopper comprises a locking protrusion formed on an outer surface of the first driving block and protruding outward to engage with an ejector housing.

Furthermore, at least one of the first and second vertical driving unit may further include a rotating unit configured to rotate the first or second lifting shaft. The rotating unit may include an internal threaded portion or an external threaded portion formed in the first or second lifting shaft, and an external threaded portion or an internal threaded portion which is formed on the lifting element corresponding to the first or second lifting shaft.

The rotating unit may include a first pulley coupled to the first or second lifting shaft, a second pulley coupled to a driving motor, and a belt coupled to the first pulley and the second pulley.

### BRIEF DESCRIPTION OF THE DRAWINGS

FIG. 1 is a diagram illustrating a concept of an ejector.

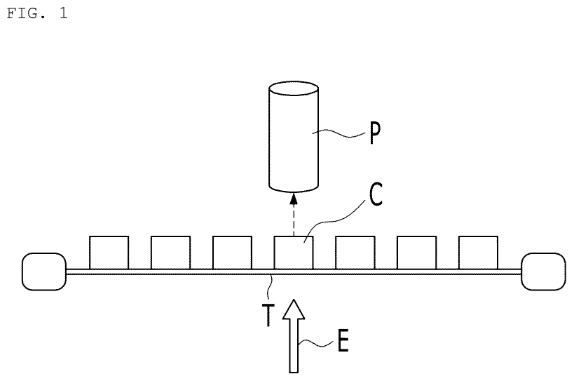

FIG. 2 is a perspective view illustrating an external shape of the ejector according to the present disclosure.

FIG. 3 is an internal cross-sectional view of the ejector according to the present disclosure.

FIG. 4 is a diagram illustrating a configuration related to an operation of a first vertical driving unit.

FIG. 5 is a diagram a configuration related to an operation of a second vertical driving unit.

FIG. 6 is an exploded view illustrating an ejecting block.

FIG. 7 is a diagram illustrating a specific embodiment of an individual ejecting block.

### DETAILED DESCRIPTION

While the present disclosure is susceptible to various modifications and alternative forms, embodiments (implantations) thereof will be described herein in detail. However, this is not intended to limit the present disclosure to particular modes of practice, and it should be understood that the present disclosure is to cover all modifications, equivalents, and alternatives falling within the spirit and scope of the present disclosure.

The terminology used herein is for the purpose of describing particular embodiments only and is not intended to be limiting the present disclosure. In the present disclosure, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “first”, “second”, etc. are used only for the purpose for distinguishing a constitutive element from other constitutive elements, but the constitutive element should not be limited to a manufacturing order, and the terms described in the detailed description may not be consistent with those described in the claims.

Before providing a detailed description of the present disclosure, to avoid confusion in terminology, expressions related to an ejecting block in the following description are defined as follows: the expressions “disposed on an outer side” and “disposed on an inner side” are based on a portion (contact portion) of the ejecting block that is exposed to the outside of an ejector hood. From the perspective of a disc 11, an “ejecting block disposed on the outer side” corresponds to an “ejecting block disposed on an upper side,” whereas an “ejecting block disposed on the inner side” corresponds to an “ejecting block disposed on a lower side.” Since such differences in the expressions are based on the contact position relative to the component serving as the reference point, they should be interpreted according to the overall context of the sentence. Such definitions of terms are to be applied equally to the claims unless otherwise specified.

The present disclosure relates to a die ejector (hereinafter referred to as “the present apparatus”) that separates a pickup-target chip from dicing tape and may broadly include an ejector module 4 provided with an ejecting block, a first driving block 5 that performs first upward or downward movement of the ejecting block, a second driving block 7 that performs second upward or downward movement of the ejecting block, a first vertical driving unit 6 that moves both the first and second driving blocks 5 and 7 simultaneously upward or downward, and a second vertical driving unit 8 that moves only the second driving block 7 upward or downward. The present apparatus has an advantage that, since the two driving blocks move upward or downward simultaneously when the first vertical driving unit 6 operates, the level of the upper portion, i.e., the contact portion, of the ejecting block can be consistently maintained during movement to a separation position or return to a standby position. In addition, there is an advantage that each ejecting operation can be implemented based on either a descending scheme or an ascending scheme selected according to a control sequence of the second vertical driving unit 8. Hereinafter, the present disclosure will be described in detail with reference to the accompanying drawings through embodiments of the present disclosure.

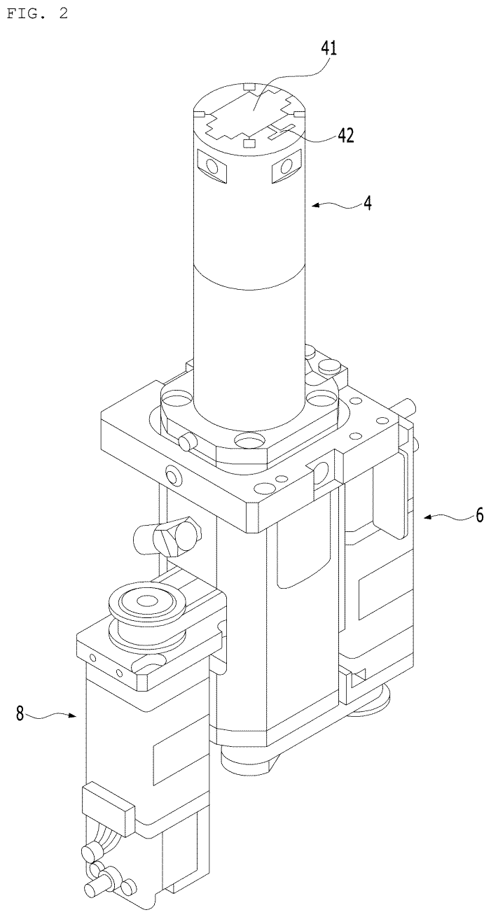

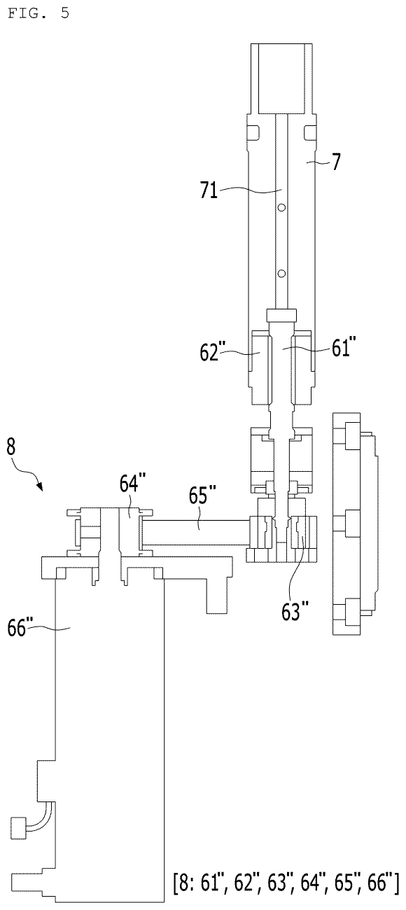

FIGS. 2 to 5 are diagrams illustrating embodiments related to the present apparatus. As illustrated, the present apparatus may include an ejector module 4 provided with an ejecting block that comes into contact with dicing tape. The ejecting block is configured to come into contact with the dicing tape and press the dicing tape, thereby enabling a semiconductor chip to be separated from the dicing tape, and has a contact portion on an upper surface thereof. The ejector module 4 may broadly include the ejecting block, an ejector housing (ejector hood), and the like.

The ejecting block may be provided in plurality, and may be moved upward or downward by a driving block described later. Preferably, the ejecting block is pushed and moved upward by upward movement of the driving block, or is moved downward together with the driving block when the pressing force applied to the ejecting block is released due to downward movement of t the driving block. A more detailed embodiment of the ejecting block will be described later. In addition, the ejector module 4 may further include

a housing that accommodates the aforementioned ejecting blocks and other components, and an ejector hood that covers an open upper portion of the housing. In FIG. 2, the ejector module 4 is illustrated. The ejector module 4 may include, in an upper surface thereof, a suction port 41 provided to secure a lower surface of the dicing tape by suction, and an exposed portion 42 provided at a center thereof to allow the ejecting blocks to be exposed. In the attached drawings, an embodiment is illustrated in which the exposed portion 42 is configured in a rectangular shape, and the suction port 41 is configured as holes arranged uniformly around the exposed portion 42. However, the configuration is not necessarily limited to the aforementioned shape.

The present apparatus may further include a first driving block 5 that implements, through the upward or downward movement, the first upward or downward movement of the ejecting blocks and a second driving block 7 that implements the second upward or downward movement of the ejecting blocks. In the present disclosure, the upward or downward movement of the ejecting blocks includes entire upward or downward movement, in which all of the ejecting blocks move upward or downward together, and stepwise upward or downward movement, in which each of the ejecting blocks moves upward or downward sequentially. The first upward or downward movement may refer to either the entire upward or downward movement or the stepwise upward or downward movement, while the second upward or downward movement may refer to the other.

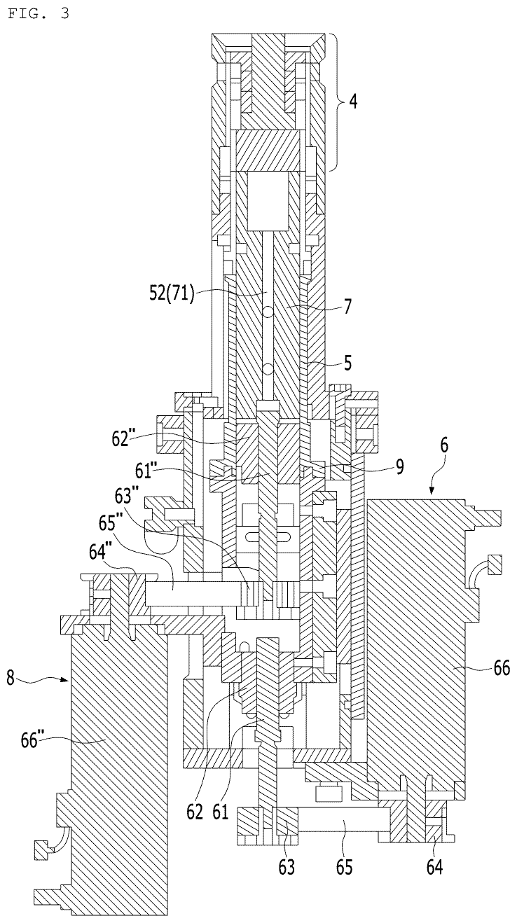

In an embodiment related to the driving blocks, as illustrated in FIGS. 3 to 5, the first driving block 5 includes a hollow space 51 therein, and the second driving block 7 may be installed in the hollow space 51. The foregoing structure is to ensure that the second driving block 7 is subordinate to the upward or downward movement of the first driving block 5. Since the second driving block 7 is installed in the first driving block 5, the second driving block 7 moves upward or downward together with the first driving block 5 when the first vertical driving unit 6 operates to move the first driving block 5 upward or downward. Preferably, a diameter, i.e., an inner diameter, of the hollow space 51 of the first driving block 5 is configured to be equal to or slightly smaller than an outer diameter of the second driving block 7.

In another embodiment related to the driving blocks, as illustrated in FIGS. 3 to 5, the present apparatus may further include a guide element that guides the upward or downward movement of the first driving block 5.

For example, the guide element may be provided in a housing of the first vertical driving unit 6 and connected to the first driving block 5.

The guide element may be, for example, an LM guide. Alternatively, the guide element may be an element including a linear shaft and a bushing.

However, the guide element is not limited to the above configurations and may include various configurations as long as the guide element can guide the upward or downward movement of the first driving block 5.

Furthermore, as shown in FIGS. 3 to 5, the first driving block 5 may include a guide portion 52 provided on an inner surface thereof. The second driving block 7 may include a sliding portion 71 constrained by the guide portion 52, and may be configured to move upward or downward along the guide portion 52. Specifically, the guide portion 52 may be configured as a groove or a protrusion having a predetermined length in the vertical direction, and the sliding portion 71 may be configured as a protrusion or a groove having a predetermined length in the vertical direction. A structure employing a sliding mechanism other than the groove-protrusion mechanism may also be utilized. The guide portion 52 and the sliding portion 71 enhance reliability in linear motion and ensure reliable upward or downward movement of the second driving block 7 during the upward or downward movement. In addition, a stopping unit for restricting the upward or downward movement of the second driving block 7 may be provided on the sliding portion 71 or the guide portion 52.

The present apparatus may include the first vertical driving unit 6 that moves upward or downward the first and second driving blocks 5 and 7 simultaneously, and the second vertical driving unit 8 that moves upward or downward only the second driving block 7. In other words, the first vertical driving unit 6 moves upward or downward the first driving block 5 and the second driving block 7 simultaneously, while the second vertical driving unit 8 moves upward or downward only the second driving block 7. In each of the vertical driving units, the configuration that physically moves the corresponding driving block upward or downward may include a configuration, such as a piston rod or a pushing plate that directly contacts and pushes the driving block upward, and may also include a configuration that provides power applicable in various forms, such as a hydraulic cylinder system, a pneumatic cylinder system, or a driving system using a motor 66. In the present disclosure, the type and kind of the vertical driving unit are not particularly limited.

Compared to providing a vertical driving unit for each ejecting block, the present apparatus has the effects of not only reducing costs by utilizing two driving blocks but also simplifying a control algorithm of the vertical driving units.

Furthermore, in the present apparatus, when the first vertical driving unit 6 operates, the first and second driving blocks 5 and 7 move upward or downward simultaneously, ensuring that an upper level of each ejecting block (e.g., a vertical level of the contact portion) remains consistent during movement to the die separation position or the standby position.

Additionally, the present apparatus has the effect of allowing selective use of a stepwise ascending scheme and a stepwise descending scheme according to the control sequence of the second vertical driving unit 8.

As a specific embodiment of the aforementioned vertical driving unit, as illustrated in FIGS. 3 to 5, the first vertical driving unit 6 may include a first lifting element 62 that is coupled to a first lifting shaft 61 and the first driving block 5, and moves upward or downward under constraint by the first lifting shaft 61. The first lifting shaft 61 may be configured as a rod-shaped element, and may preferably include a thread (e.g., a ball screw) in a certain section. Furthermore, the first lifting element 62 may be configured as a nut-shaped element (hereinafter referred to as a nut), and may preferably include, in a certain section, a thread that correspond to the thread of the first lifting shaft 61. In this embodiment, when the first lifting shaft 61 is rotated by a rotating unit described later, the first lifting element 62 moves upward and downward along the threads. It is also apparent that a configuration may be further required to prevent the first lifting element 62 from rotating together with the first lifting shaft 61 during the rotation of the first lifting shaft 61.

As another example, the first lifting shaft 61 may be a stator of a linear motor, in which case the second lifting element 62 may be a mover of the linear motor (e.g., a moving slider).

The linear motor is a well-known product used in various fields, and a more detailed description thereof will be omitted.

In addition, as illustrated in FIGS. 3 to 5, the second vertical driving unit 8 may also include, in the same manner as the first vertical driving unit 6, a second lifting shaft 61″ (a ball screw or a stator of a linear motor) and a second lifting element 62″ (a nut-shaped element or a mover of the linear motor) that is coupled to the second driving block 7 and moves upward and downward under constraint by the second lifting shaft 61″. In the case the first vertical driving unit 6 and the second vertical driving unit 8 are configured with the same structure, a manufacturing cost reduction effect can be achieved due to the uniformity of component configuration.

More specifically, as mentioned above, the first vertical driving unit 6 further includes a rotating unit that rotates the first lifting shaft 61. The rotating unit may be configured such that the first lifting shaft 61 includes an internal threaded portion or an external threaded portion, and the first lifting element 62 includes an external threaded portion or an internal threaded portion. Furthermore, the second vertical driving unit 8 may also include a rotating unit having the same structure as the first vertical driving unit 6.

As a specific embodiment of the aforementioned rotating unit, as illustrated in FIGS. 3 to 5, the rotating unit may include a first pulley 63 or 63″ coupled to the first lifting shaft 61 or the second lifting shaft 61″, a second pulley 64 or 64″ coupled to a driving motor 66 or 66″, and a belt 65 or 65″ coupled to both the first pulley 63 or 63″ and the second pulley 64 or 64″. In the foregoing rotating unit, when the second pulley 64 is rotated by the driving motor 66, the first pulley 63 is also rotated together by the belt 65, thereby causing the first lifting shaft 61, which is coupled to the first pulley 63, to rotate. Preferably, the first pulley 63 may be coupled to a lower end of the first lifting shaft 61, and the first lifting shaft 61 may have a thread provided on an upper side of the lower end to which the first pulley 63 is coupled.

As shown in FIGS. 3 to 5, the second lifting shaft 61″ and the second lifting element 62″ of the second vertical driving unit 8 may be installed in the hollow space 51 of the first driving block 5. The aforementioned structure not only allows the second driving block 7 to be installed in the hollow space 51 of the first driving block 5 but also interlinks the second driving block 7 and the second vertical driving unit 8 with the upward or downward movement of the first driving block 5, thereby realizing a multi-vertical driving unit with a subordinate structure that is a key technical feature of the present disclosure.

As illustrated in FIGS. 3 to 5, the present apparatus may further include a stopper configured to limit the upward movement of the first driving block 5. The stopper restricts the upward movement of the first driving block 5 when the second driving block 7 moves upward by the operation of the second vertical driving unit 8, ensuring that the operation of the second vertical driving unit 8 moves only the second driving block 7 upward. That is, due to the stopper, the present apparatus ensures that only the second driving block 7 moves upward when the second vertical driving unit 8 operates.

As an embodiment related to the stopper, the stopper may include a locking protrusion 9 that is formed on an outer surface of the first driving block 5 and protrudes outward to engage with the ejector housing. When the first driving block 5 moves upwards, the locking protrusion 9 moves upward together with the first driving block 5, and engages with a step formed inside the ejector housing, preventing further the upward movement of the first driving block 5. Accordingly, when the second vertical driving unit 8 operates, the first driving block 5 does not move upward.

The guide element that guides the first driving block 5 may be provided with a stopper that restricts the further upward movement of the first driving block 5. For example, the stopper may be formed by protruding from the LM guide.

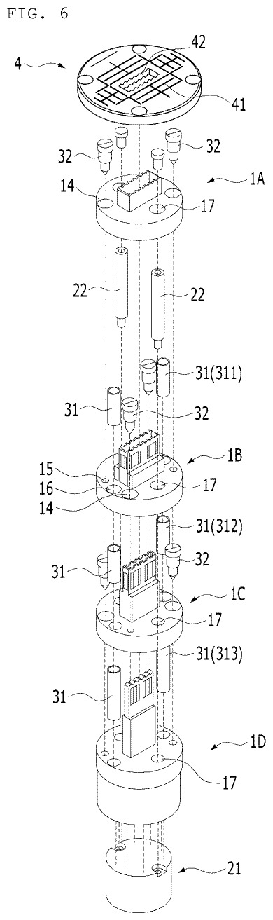

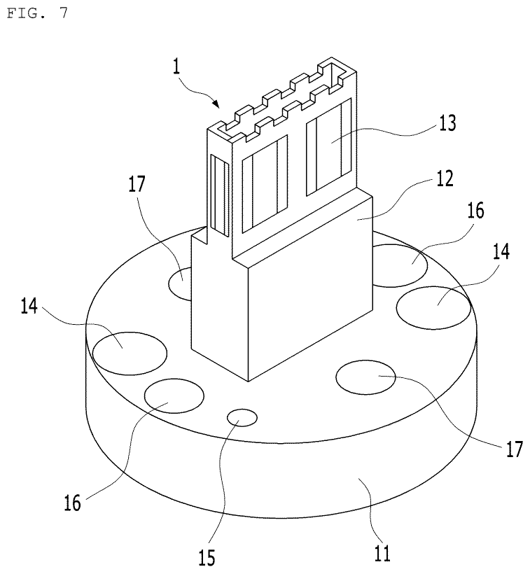

FIGS. 6 and 7 are diagrams illustrating a specific embodiment for explaining the ejecting g blocks and an operating mechanism thereof according to the present disclosure. For convenience of explanation, the illustrated embodiment describes the case where four ejecting blocks are used as an example; however, it should be noted that the present disclosure is not limited thereto. In the present disclosure, the ejecting blocks are characterized in that a lifting height of an nth ejecting block is set greater than a lifting height of a second ejecting block 1B, which is an (n-1)th block positioned relatively outward of the nth ejecting block. In other words, the ejecting block at the exact center has the highest lifting height, while the ejecting block at the outermost side has the lowest lifting height, ensuring that dicing tape T is separated sequentially from the outer side toward the center.

As a specific embodiment of the ejecting block, as illustrated in FIG. 7, each ejecting block 1 includes a disc 11, a column 12 formed vertically on the disc 11, a pusher 13 provided on an upper portion of the column 12, and a through-hole 14, a threaded hole 15, a mounting recess 16, and an interlocking hole 17 that are formed in disc 11. The disc 11 has a hollow space therein.

Specifically, the disc 11 is a disc-shaped body that serves as a base of the ejecting block 1. The disc shape corresponds to an overall cylindrical shape of the present apparatus; however, it is not necessarily required to be formed in a disc shape. Although the disc 11 may have various forms, including polygonal or irregular shapes, it is preferable to have a somewhat standardized shape, such as a disc or a polygonal plate, to ensure the stability in upward or downward movement of the block.

The column 12 is configured to be vertically connected to the disc 11, and the length thereof is determined according to a height difference between the disc 11 and the ejector hood 4. Accordingly, the column 12 of an nth ejecting block that is positioned at the innermost side (for example, referring to a fourth ejecting block 1D described later) is configured to be longer than the column 12 of a first ejecting block 1A positioned at the outermost side, thereby allowing the heights of the respective pushers 13 of the ejecting blocks 1 to be aligned at the same level in a standby state before being exposed above the ejector hood 4. Since the height of the pusher 13 of each ejecting block 1 may not necessarily be configured to be the same, each ejecting block 1 is ultimately configured such that the sum of the height of the column 12 and the height of the pusher 13 is the same.

The pusher 13 is configured to contact the dicing tape T and push up the dicing tape T, with an upper surface of the pusher 13 serving as a contact portion that comes into contact with the dicing tape T. The column 12 and the pusher 13 may be configured in a rectangular pillar shape according to the shape of the dicing tape T but are not necessarily limited thereto. The pusher 13 may have a smaller cross-sectional area than the column 12 such that a step is formed between the column 12 and the pusher 13. In addition, the contact portion, which is the upper surface of the pusher 13, may have a concave-convex structure in which protrusions and recesses are alternately arranged. The concave-convex structure maintains pressing efficiency on the dicing tape T while allowing the pusher 13 to easily detach from a lower surface of the dicing tape T when the pressing force is released.

As shown in FIGS. 6 and 7, each of the disc 11, the column 12, and the pusher 13 has a hollow space therein, allowing the column 12 and the pusher 13 of an nth ejecting block (for example, a third ejecting block 1C described later) positioned relatively inward to be received in the hollow space of an (n-1)th ejecting block (for example, referring to the second ejecting block 1B described later) positioned relatively outward. Through the aforementioned configuration, the ejecting blocks are stacked in an overlapping manner, and are stacked with a predetermined gap formed therebetween by an elastic member 31 described later. It is apparent that the hollow space of each ejecting block may be formed in a shape corresponding to the shape of the column 12 and the pusher 13 of the overlapping (n-1)th ejecting block.

The through-hole 14 is formed in the disc 11 and is configured to allow a bolt 32, which connects two adjacent ejecting blocks, to pass through. The through-hole 14 may be a hole formed throughout the entire disc 11 along the vertical direction.

The threaded hole 15 is formed in the disc 11 and is configured such that the bolt 32 passing through the through-hole 14 is tightened into the threaded hole 15. The threaded hole 15 has a thread corresponding to that of the bolt 32 and may be a hole formed partially or entirely along the vertical direction of the disc 11. The threaded hole 15 may not be formed in the disc 11 of the first ejecting block 1A, which is disposed at an uppermost position.

In addition, the mounting recess 16 is configured to receive the elastic element 31 that limits upward movement of the corresponding ejecting block by restricting the spacing between two adjacent ejecting blocks to a certain length or less. The mounting recess 16 is formed not only in an upper surface but also in a lower surface of the disc 11 and may be a recess formed partially along the vertical direction of the disc 11. The mounting recess 16 may not be formed in the lower surface of the disc 11 of the central ejecting block that is disposed at a lowermost position (referring to the fourth ejecting block 1D described later).

The interlocking hole 17 is configured to allow an interlocking rod 22, described later, to pass through and is formed in the disc 11. The interlocking hole 17 may be a hole formed entirely along the vertical direction of the disc 11. The interlocking hole 17 is formed throughout, from the disc 11 of the first ejecting block 1A, which is disposed at the uppermost position, to a lifting block 21, which is disposed at the lowermost position. Accordingly, the upward or downward movement of all of the ejecting blocks may be interlocked with the upward or downward movement of the lifting block 21.

Next, as illustrated in FIGS. 6 and 7, the present apparatus may further include a lifting unit for implementing the upward or downward movement of the ejecting blocks. The lifting unit may include a driving module that moves the ejecting blocks upward or downward. The driving module may include a configuration that physically moves the ejecting blocks upward or downward and a configuration that provides power. The configuration that physically moves the ejecting blocks upward or downward may be a configuration that directly contacts and pushes up the blocks, such as a piston rod or a pushing plate. The configuration that provides power may employ various structures, such as a hydraulic cylinder system, a pneumatic cylinder system, or a motor- driven system, and the present disclosure does not particularly limit the type thereof.

As shown in FIGS. 6 and 7, the lifting unit may further include a lifting block 21, which is provided below the central ejecting block (the fourth ejecting block 1D in FIG. 2) that is disposed at the innermost position among the ejecting blocks, to move all of the ejecting blocks upward or downward. More specifically, as shown in FIG. 2, the lifting block 21 has a shape similar to the disc 11 of the ejecting block and has a shape corresponding to the hollow space of the central ejecting block so that the lifting block 21 can be inserted into the hollow space of the central ejecting block. In the illustrated embodiment, the lifting block 21 has a cylindrical shape. The lifting block 21 moves upward or downward by a second driving module, described later, and pushes up all of the ejecting blocks, including the central ejecting block, during upward movement.

The driving module may include a second driving module that moves the lifting block 21 upward or downward, and a first driving module that moves the central ejecting block upward or downward. The second driving module is provided below the lifting block 21 to move the lifting block 21 upward, thereby causing upward movement of all of the ejecting blocks, including the lifting block 21. Furthermore, the module moves upward the central ejecting block, which is the ejecting block disposed at the innermost position, thereby causing upward movement of each of the ejecting blocks. In other words, when the second driving module moves the lifting block 21 upward, all of the ejecting blocks move upward together. When the first driving module moves the central ejecting block CB upward, each of the ejecting blocks sequentially moves upward due to a restriction unit, described later.

In addition, as shown in FIGS. 6 and 7, the lifting unit may further include the interlocking rod 22, which is installed to penetrate sequentially from the first ejecting block 1A, positioned at an outermost side among the ejecting blocks, to the lifting block 21. As described above, all of the ejecting blocks have the respective interlocking holes 17 through which the interlocking rod 22 passes. The interlocking rod 22 is installed to penetrate all of the interlocking holes 17, extending from the uppermost first ejecting block 1A to the lowermost lifting block 21. Accordingly, when the lifting block 21 moves upward, all of the ejecting blocks, which are functionally coupled by the interlocking rod 22, simultaneously move upward. The interlocking rod 22 also ensures linear movement of each of the ejecting blocks during the upward or downward movement, thereby contributing to a reliable upward or downward movement operation.

In the present disclosure, all of the ejecting blocks are primarily moved upward as a whole by the first driving module so that all of the ejecting blocks are exposed outside an exposed portion 42 of the ejector hood 4. In this state, the second driving module restricts upward movement of each ejecting block sequentially from the outer side, thereby forming stepwise upward movement with a convex central portion, facilitating the separation of the dicing tape T. The following restriction unit corresponds to an essential component for implementing the stepwise upward movement.

The present disclosure, compared to a structure equipped with a single vertical driving unit, primarily enables separation of the outer periphery of the dicing tape T first, followed by the separation of the dicing tape to the central portion in stages, thereby allowing more reliable and easier separation of the dicing tape T. Furthermore, because only two vertical driving units are provided, the present disclosure may not only reduce costs compared to providing a vertical driving unit for each ejecting block but may also simplify a control algorithm of the vertical driving units.

Next, as illustrated in FIGS. 2 to 7, the present apparatus may further include a restriction unit configured to limit the lifting height of each of the ejecting blocks.

The restriction unit may include an upward movement restriction unit that limits the lifting height of each of the ejecting blocks, and a spacing restriction unit that limits the spacing between the ejecting blocks. The upward movement restriction unit limits the lifting height of each of the ejecting blocks during upward movement of the ejecting blocks, preventing the ejecting block from moving upward beyond a certain height, thereby implementing the stepwise upward movement of the ejecting blocks, which is the key feature of the present disclosure. Furthermore, the spacing restriction unit limits the maximum spacing between the ejecting blocks, ensuring that during downward movement, the spacing between each pair of ejecting blocks does not exceed a certain distance, thereby allowing all of the ejecting blocks to move downward in an interlocked manner.

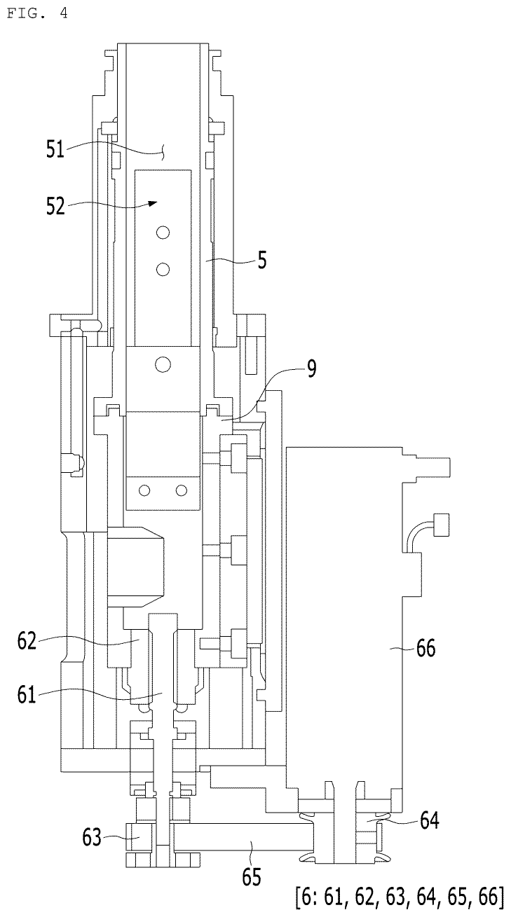

As a specific embodiment of the upward movement restriction unit, as illustrated in FIGS. 2 and 4, the upward movement restriction unit may include an elastic element 31 provided between the nth ejecting block and the (n-1)th ejecting block. In a more specific embodiment, the elastic element 31 may be a spring. Here, it is assumed that the concepts of “first” and “second” refer to relative positions, as in the nth and (n-1)th ejecting blocks, and do not designate a specific ejecting block among the multiple ejecting blocks. The elastic element 31 is compressed during the upward movement of the ejecting block, providing resistance to the lifting force generated by the driving module, thereby restricting the upward movement of the ejecting block.

Furthermore, to implement the stepwise upward movement operation of the present disclosure as described above, the ejecting blocks may include the first ejecting block 1A, the second ejecting block 1B disposed at an inner side of the first ejecting block 1A, the third ejecting block 1C disposed at an inner side of the second ejecting block 1B, and the fourth ejecting block 1D disposed at an inner side of the third ejecting block 1C, as illustrated in FIG. 4.

The elastic element 31 may include a first elastic element 311 provided between the first ejecting block 1A and the second ejecting block 1B, a second elastic element 312 provided between the second ejecting block 1B and the third ejecting block 1C, and a third elastic element 313 provided between the third ejecting block 1C and the fourth ejecting block 1D.

Here, an elastic force of the second elastic element 312 may be configured to be greater than that of the first elastic element 311, and an elastic force of the third elastic element 313 may be configured to be greater than that of the second elastic element 312.

Accordingly, when a pressure is applied such that the first elastic element 311 is fully compressed while the second elastic element 312 is not fully compressed, the complete compression of the first elastic element 311 causes the first ejecting block 1A and the second ejecting block 1B to come into contact with each other, preventing further upward movement of the second ejecting block 1B. When a pressure sufficient to fully compress the second elastic element 312 in addition to the first elastic element 311 is applied due to the upward movement by the first driving module, the complete compression of the second elastic element 312 causes the second ejecting block 1B and the third ejecting block 1C to come into contact with each other, thereby preventing further upward movement of the third ejecting block 1C. That is, the more inwardly positioned the ejecting block is, the stronger the elastic element 31 restricting the upward movement of the ejecting block is configured to be. Through the aforementioned arrangement, the upward movement of the ejecting blocks is sequentially restricted from the outer side to the inner side, ultimately allowing only the central ejecting block to move upward. As a result, when viewed from the side, the ejecting blocks form a stepped structure having a mountain-like shape with a convex center. FIG. 4 shows that the elastic forces of the first to third elastic elements 311 to 313, which restrict the upward movement of the four ejecting blocks, increase in reverse order.

As an embodiment related to the elastic element 31, a difference in elastic force between the first elastic element 311 and the second elastic element 312 may be determined by a compressed deformation length or a spring constant. Generally, factors determining the magnitude of the elastic force of the elastic element 31 include the spring constant, which is influenced by the material of the elastic element 31, a coil diameter of the elastic element 31, and an outer diameter of the elastic element 31, and the compressed deformation length of the spring. In the present embodiment, to reduce manufacturing costs associated with spring production and to precisely control the elastic force, the spring constant is selected to be the same, and only the compression length of the spring is used to adjust the elastic force.

A specific embodiment of the spacing restriction unit is illustrated in FIGS. 2 and 5 to 7. The spacing restriction unit may include the bolt 32 provided between the nth ejecting block and the (n-1)th ejecting block.

Referring to FIGS. 6 and 7, the bolt 32 may include a head portion 321 having a diameter larger than that of the through-hole 14 formed in the (n-1)th ejecting block, a body portion 322 that is connected to the head portion 321 and has a diameter smaller than or equal to that of the through-hole 14, and a threaded portion 323 that is connected to the body portion 322 and engaged into the threaded hole 15 formed in the nth ejecting block. The body portion 332 serves as a non-threaded section formed without thread formation, and as a result, the spacing between the ejecting blocks is adjusted according to the length of the body portion 332. In the case where the spacing restriction unit is implemented using the bolt 32 as described above, when the nth ejecting block moves upward and comes into contact with the (n-1)th ejecting block, the height of the bolt 32 relative to the (n-1)th ejecting block also increases, causing the (n-1)th ejecting block to be positioned closer to the threaded portion 323. In this state, when the nth ejecting block moves downward, the head portion 321 of the bolt 32 is engaged with an edge portion of the through-hole 14 in the (n-1)th ejecting block, thereby interlocking the downward movement of the nth ejecting block and the (n-1)th ejecting block. The state in which the edge portion of the through-hole 14 and the head portion 321 are in contact defines the maximum spacing between the nth ejecting block and the (n-1)th ejecting block, preventing further separation.

The present disclosure having the above-mentioned configuration and features has the effects of not only reducing costs by utilizing two driving blocks compared to providing a vertical driving unit for each ejecting block, but also simplifying a control algorithm of the vertical driving units.

Furthermore, in the present apparatus, when a first vertical driving unit operates, first and second driving blocks move upward or downward simultaneously, ensuring that an upper level of each ejecting block (e.g., a vertical level of a contact portion) remains consistent during movement to a die separation position or a standby position.

Additionally, the present apparatus has the effect of allowing selective use of a stepwise ascending scheme and a stepwise descending scheme according to a control sequence of a second vertical driving unit.

The present disclosure described above with reference to the accompanying drawings may be variously modified and changed by those of ordinary skill in the art, and such modifications and changes that are not limited by the claims should be construed as being included in the scope of the present disclosure.

What is claimed is:

1. A die ejector comprising:
an ejector module including an ejecting block that comes into contact with dicing tape; a first driving block configured to perform, through upward or downward movement thereof, first upward or downward movement of the ejecting block; a second driving block configured to perform, through upward or downward movement thereof, second upward or downward movement of the ejecting block; a first vertical driving unit configured to move the first and second driving blocks upward or downward simultaneously; and
a second vertical driving unit configured to move only the second driving block upward or downward.

2. The die ejector of claim 1, wherein the first vertical driving unit comprises a first lifting shaft, and a first lifting element coupled to the first driving block and configured to move upward or downward under constraint by the first lifting shaft.

3. The die ejector of claim 2, wherein the second vertical driving unit comprises a second lifting shaft, and a second lifting element coupled to the second driving block and configured to move upward or downward under constraint by the second lifting shaft.

4. The die ejector of claim 3,
wherein the first driving block includes a hollow space therein, and
wherein the second driving block is installed in the hollow space.

5. The die ejector of claim 4, wherein the second lifting shaft and the second lifting element of the second vertical driving unit are installed in the hollow space of the first driving block.

6. The die ejector of claim 3,
wherein the first driving block comprises a guide portion provided on an inner surface thereof, and
wherein the second driving block comprises a sliding portion constrained by the guide portion so that the second driving block moves upward or downward along the guide portion.

7. The die ejector of claim 3, further comprising a stopper configured to limit upward movement of the first driving block so that when the second vertical driving unit operates, only the second driving block moves upward.

8. The die ejector of claim 7, wherein the stopper comprises a locking protrusion formed on an outer surface of the first driving block and protruding outward to engage with an ejector housing.

9. The die ejector of claim 3, wherein at least one of the first and second vertical driving units further comprises a rotating unit configured to rotate the first or second lifting shaft, wherein the first or second lifting shaft includes an internal threaded portion or an external threaded portion, and the first or second lifting element includes an external threaded portion or an internal threaded portion.

10. The die ejector of claim 9, wherein the rotating unit comprises a first pulley coupled to the first or second lifting shaft, a second pulley coupled to a driving motor, and a belt coupled to the first pulley and the second pulley.

11. The die ejector of claim 2, wherein the first or second lifting shaft comprises a ball screw or a stator of a linear motor, and the first or second lifting element comprises a nut or a mover of the linear motor.
